(19) United States
(12) Patent Application Publication
(10) Pub. No.: US 2025/0036030 A1
(43) Pub. Date: Jan. 30, 2025

(54) AUTO PARAMETER TUNING FOR CHARGED PARTICLE INSPECTION IMAGE ALIGNMENT

(71) Applicant: ASML Netherlands B.V., Veldhoven (NL)

(72) Inventors: Haoyi LIANG, Sunnyvale, CA (US); Ye GUO, San Jose, CA (US); Zhichao CHEN, San Jose, CA (US)

(73) Assignee: ASML Netherlands B.V., Veldhoven (NL)

(21) Appl. No.: 18/716,111

(22) PCT Filed: Nov. 18, 2022
(86) PCT No.: PCT/EP2022/082520

§ 371 Date: Jun. 3, 2024

Related U.S. Application Data
(60) Provisional application No. 63/361,394, filed on Dec. 15, 2021.

(51) Int. Cl. G03F 7/00; G03F 1/84; G06T 7/00; G06T 7/30; H01L 21/66

(52) U.S. Cl. CPC G03F 7/7065; G03F 1/84; G03F 7/70655; G06T 7/0004; G06T 7/30; H01L 22/12; G06T 2207/10061; G06T 2207/30148

(57) ABSTRACT

An improved method and system for image alignment of an inspection image are disclosed. An improved method comprises acquiring an inspection image, acquiring a reference image corresponding to the inspection image, acquiring a target alignment between the inspection image and the reference image based on characteristics of the inspection image and the reference image, estimating an alignment parameter based on the target alignment, and applying the alignment parameter to a subsequent inspection image.

### CROSS-REFERENCE TO RELATED APPLICATIONS

This application claims priority of U.S. application 63/361,394 which was filed on Dec. 15, 2021 and which is incorporated herein in its entirety by reference.

### TECHNICAL FIELD

The embodiments provided herein relate to an image alignment technology, and more particularly to a result-oriented auto parameter tuning mechanism for a charged-particle beam inspection image.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Inspection images such as SEM images can be used to identify or classify a defect(s) of the manufactured ICs. To improve defect detection performance, obtaining an accurate alignment between a SEM image and corresponding design layout data is desired.

### SUMMARY

The embodiments provided herein disclose a particle beam inspection apparatus, and more particularly, an inspection apparatus using a plurality of charged particle beams.

Some embodiments provide a method for image alignment of an inspection image. The method comprises acquiring an inspection image, acquiring a reference image corresponding to the inspection image, acquiring a target alignment between the inspection image and the reference image based on a pattern of the inspection image and a corresponding pattern of the reference image, evaluating a first alignment parameter combination and a second alignment parameter combination based on the target alignment, selecting, between the first and second alignment parameter combinations, one alignment parameter combination based on the evaluation, and applying the selected alignment parameter combination to the reference image.

Some embodiments provide an apparatus for image alignment of an inspection image, comprising: a memory storing a set of instructions; and at least one processor configured to execute the set of instructions to cause the apparatus to perform: acquiring an inspection image, acquiring a reference image corresponding to the inspection image, acquiring a target alignment between the inspection image and the reference image based on characteristics of the inspection image and the reference image, estimating an alignment parameter based on the target alignment, and applying the alignment parameter to a subsequent inspection image.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example multi-beam tool that can be a part of the example charged-particle beam inspection system of FIG. 1, consistent with embodiments of the present disclosure.

FIG. 3 illustrates an example alignment result between a SEM image and a reference image without parameter tuning according to some embodiments of the present disclosure.

FIG. 4 is a block diagram of an example alignment parameter tuning system, consistent with embodiments of the present disclosure.

FIG. 5A illustrates an inspection image and a reference image, consistent with embodiments of the present disclosure.

FIG. 5B illustrates an inspection image aligned with a reference image, consistent with embodiments of the present disclosure.

FIG. 5C is an example alignment parameter table, consistent with embodiments of the present disclosure.

FIG. 6 illustrates an example alignment result after applying estimated alignment parameter(s) according to some embodiments of the present disclosure.

FIG. 7 illustrates a first example alignment result comparison for a SEM image before and after applying estimated alignment parameter(s) according to some embodiments of the present disclosure.

FIG. 8 illustrates a second example alignment result comparison for a SEM image before and after applying estimated alignment parameter(s) according to some embodiment of the present disclosure.

FIG. 9 is a process flowchart representing an exemplary alignment parameter tuning method, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (SCPM). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

As the physical sizes of IC components continue to shrink, accuracy and yield in defect detection become more important. Inspection images such as SEM images can be used to identify or classify a defect(s) of the manufactured ICs. To improve defect detection performance, obtaining an accurate alignment between a SEM image and corresponding design layout data is desired. An accurate die to database (D2DB) alignment can be achieved by fine tuning of various alignment parameters. Under current D2DB alignment techniques, alignment parameters are manually tuned based on appearance comparison between a SEM image and corresponding design layout. However, such parameter tuning may take a repetitive trial-and-error process, which is time-consuming and tedious. Further, for challenging alignment cases, it may even be difficult to find an optimal alignment parameter combination with manual tuning.

Embodiments of the disclosure may provide a result-oriented auto parameter tuning technique for D2DB alignments. According to some embodiments of the present disclosure, a user-friendly parameter tuning method for aligning SEM images with design layout data can be provided. According to some embodiments of the present disclosure, a user can provide a target alignment result by dragging a SEM image to a target position on design layout such that the SEM image matches the design layout. According to some embodiments of the present disclosure, a back-end algorithm can automatically search for an optimal alignment parameter combination based on a target alignment result, e.g., provided by user input. According to some embodiments of the present disclosure, a D2DB alignment parameter tuning technique that can shortens alignment parameter tuning cycles can be provided.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A. or B, or A and B. As a second example, if it is stated that a component may include A, B, or C, then, unless specifically stated otherwise or infeasible, the component may include A, or B, or C, or A and B, or A and C, or B and C, or A and B and C.

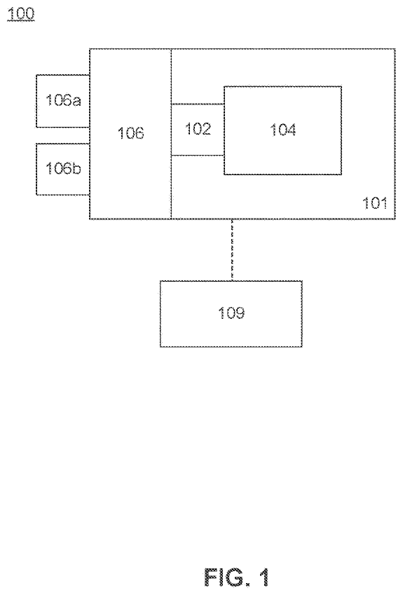

FIG. 1 illustrates an example electron beam inspection (EBI) system 100 consistent with embodiments of the present disclosure. EBI system 100 may be used for imaging. As shown in FIG. 1. EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

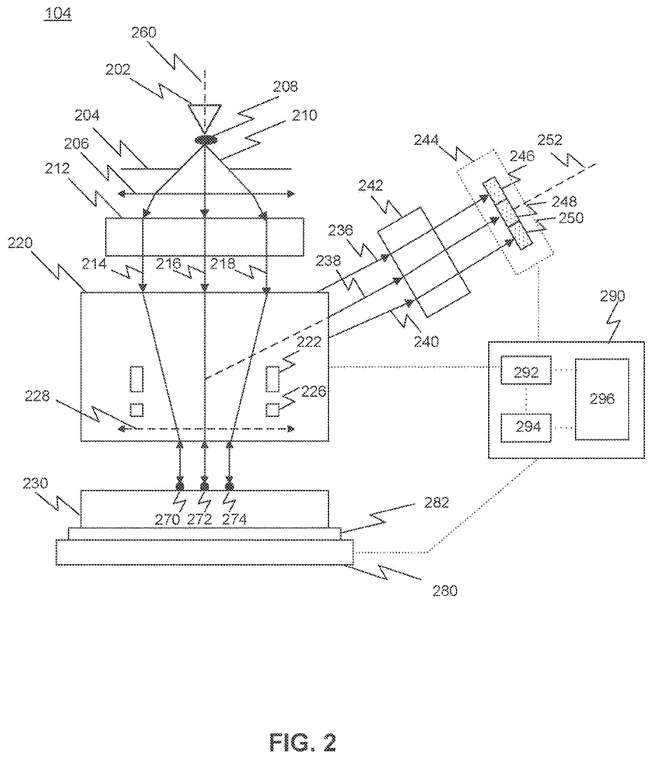

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

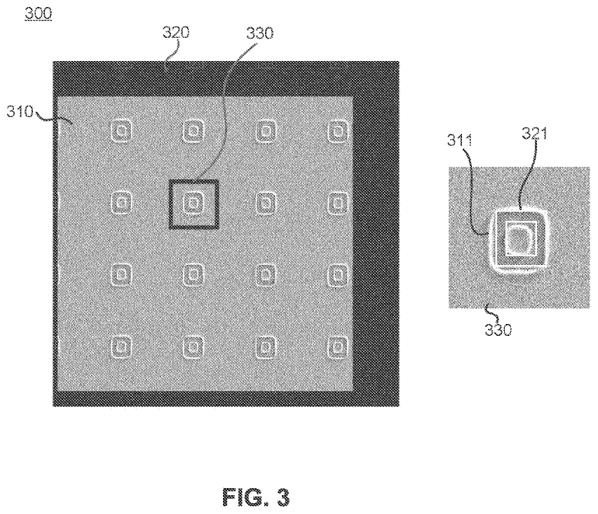

FIG. 3 illustrates an example alignment result between a SEM image and a reference image without parameter tuning according to some embodiments of the present disclosure. In FIG. 3, a SEM image 310 and a corresponding GDS image 320 are aligned according to an alignment algorithm. In some embodiments, a cross-correlation maximization algorithm can be used as an alignment algorithm. In a cross-correlation maximization algorithm, an alignment that maximizes cross-correlation between a SEM image and a GDS image can be outputted as an alignment result. In some embodiments, a GDS image can be rendered to generate an image similar to a SEM image before applying an alignment algorithm. An alignment result 300 of FIG. 3 may be obtained based on a default parameter setting without fine tuning of alignment parameters. In FIG. 3, alignment result 300 includes an example portion 330 of which enlarged image is illustrated on the right side. In the enlarged image of portion 330, a pattern 311 of SEM image 310 has two layered rectangular shapes having blurred bright edges. A corresponding pattern 321 of GDS image 320 is also indicated in portion 330 and has two layered rectangles having sharp edges. As shown in FIG. 3, pattern 311 of SEM image 310 is snapped to the bottom left corner of pattern 321 rather than matching a center of pattern 311 with a center of pattern 321. This is called snapping, which is one of the most common alignment challenges. Snapping is usually caused by asymmetric gray level in SEM images caused by electron charging. A SEM image having asymmetric gray level tends to be aligned to one side or one point of a corresponding GDS pattern rather than a center of the GDS pattern.

While snapping is explained as an example to demonstrate challenges faced in D2DB alignment, there are other difficulties that hinder an accurate alignment, such as uneven gray level of SEM images, repetitive pattern design, or other adversarial imaging conditions including noise. In order to resolve such alignment issues and to have an accurate alignment, two factors in general can be considered: 1. how to render a GDS image; and 2. how to preprocess a SEM image before alignment. For example, parameter(s) for rendering process can be tuned to render a GDS image to a gray level image similar to a corresponding SEM image. Further, one or more image processing operations can be determined to be performed on a SEM image for preprocessing the SEM image before alignment to achieve an accurate alignment between the SEM image and a corresponding GDS image. In some cases, parameter(s) for performing one or more image processing operations can also be tuned. Under current D2DB alignment techniques, such alignment parameters are manually tuned based on an appearance comparison between a SEM image and corresponding design layout. However, such parameter tuning may take a repetitive trial-and-error process, which is time consuming and tedious. In particular, for challenging alignment cases, it may even be difficult to find an optimal alignment parameter combination with manual tuning due to operator's limited expertise on a series of image processing techniques or a time restriction. While SEM/SCPM images are referred to throughout, it is appreciated that other type of images may be used, such as optical images.

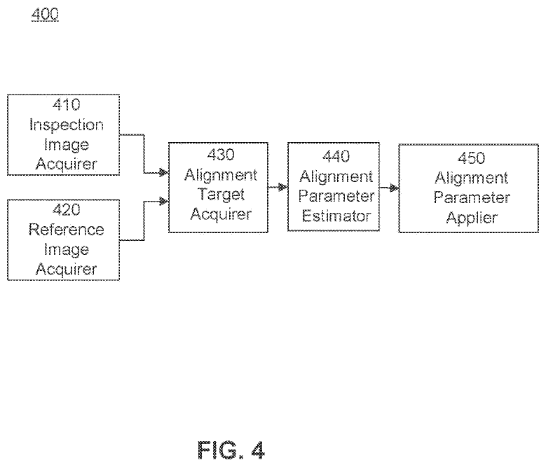

Reference is now made to FIG. 4, which is a block diagram of an example alignment parameter tuning system, consistent with embodiments of the present disclosure. In some embodiments, an alignment parameter tuning system 400 comprises one or more processors and memories. It is appreciated that in various embodiments alignment parameter tuning system 400 may be part of or may be separate from a charged-particle beam inspection system (e.g., EBI system 100 of FIG. 1). In some embodiments, alignment parameter tuning system 400 may include one or more components (e.g., software modules, circuitry, or any combination thereof) that can be implemented in controller 109 or system 290 as discussed herein. In some embodiments, alignment parameter tuning system 400 may include or may be associated with user interface(s) for receiving user input(s) or for presenting information to a user, such as a displayer, a keyboard, a mouse, a controller, etc. As shown in FIG. 4, alignment parameter tuning system 400 may comprise an inspection image acquirer 410, a reference image acquirer 420, a target alignment acquirer 430, an alignment parameter estimator 440, and an alignment parameter applier 450.

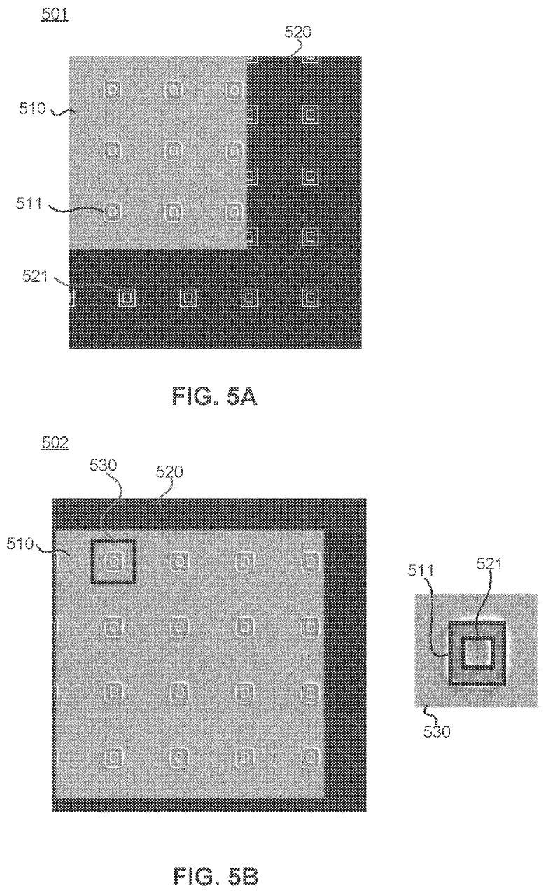

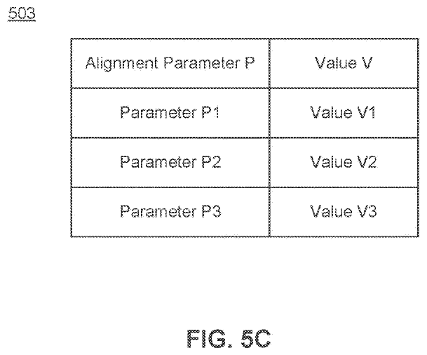

According to some embodiments of the present disclosure, inspection image acquirer 410 can acquire an inspection image as an input image. In some embodiments, an inspection image is a SEM image of a sample or a wafer. In some embodiments, an inspection image can be an inspection image generated by, e.g., EBI system 100 of FIG. 1 or electron beam tool 104 of FIG. 2. In some embodiments, inspection image acquirer 410 may obtain an inspection image from a storage device or system storing the inspection image. FIG. 5A illustrates an example inspection image 510 including a pattern 511.

Referring back to FIG. 4, according to some embodiments, reference image acquirer 420 can acquire a reference image corresponding to an inspection image acquired by inspection image acquirer 410. In some embodiments, a reference image can be a layout file for a wafer design corresponding to the inspection image. The layout file can be a golden image or in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a reference image can be an image rendered from the layout file. FIG. 5A illustrates a reference image 520 corresponding to inspection image 510. As shown in FIG. 5A, reference image 520 includes a pattern 521 corresponding to pattern 511 of inspection image. In FIG. 5A, inspection image 510 and reference image 520 are not aligned while inspection image 510 and reference image 510 overlap each other.

Referring back to FIG. 4, according to some embodiments of the present disclosure, target alignment acquirer 430 can acquire a target alignment between an inspection image and a reference image corresponding to the inspection image. In some embodiments, a target alignment can be pattern matching information between an inspection image and a reference image. In some embodiments, a target alignment can be acquired from user input aligning an inspection image with a corresponding reference image.

FIG. 5B illustrates inspection image 510 aligned with reference image 520, consistent with embodiments of the present disclosure. According to some embodiments, inspection image 510 and reference image 520 can be positioned such that pattern 511 of inspection image 510 and corresponding pattern 521 of reference image 520 match each other. In some embodiments, a user may move inspection image 510 to a position such that pattern 511 of inspection image 510 overlaps with corresponding pattern 521 of reference image 520. As shown in enlarged image of portion 530 in FIG. 5B, inspection image 510 and reference image 520 can be positioned such that a center of pattern 511 of inspection image 510 and a center of pattern 521 of reference image 520 matches. According to some embodiments of the present disclosure, alignment information between inspection image 510 and reference image 520 illustrated in FIG. 5B can be a target alignment between inspection image 510 and reference image 520. In some embodiments, FIG. 5A and FIG. 5B may illustrate images 501 and 502 displayed on a displayer (not shown), and a user may move inspection image 510 from a position in FIG. 5A to a position in FIG. 5B, e.g., by dragging inspection image 510 to a target position to provide a target alignment.

Referring back to FIG. 4, according to some embodiments of the present disclosure, alignment parameter estimator 440 can estimate alignment parameter(s) based on a target alignment acquired by target alignment acquirer 430. In some embodiments, a target alignment acquired by target alignment acquire 430 provide guidance how to tune alignment parameter(s) to achieve the target alignment. According to some embodiments of the present disclosure, alignment parameter(s) can be determined such that an alignment between an inspection image and a reference image after applying the estimated alignment parameter(s) can be as close as possible to the target alignment.

According to some embodiments of the present disclosure, alignment parameter(s) can be estimated based on an equation represented as follows:

$$w ⋆ = {ArgMin}_{w} {‖ {AA}_{w} ( GDS , S E M ) - T ‖}_{2}^{2} \qquad Equation l$$

Here, W represents an alignment parameter set. T represents a target alignment acquired by target alignment acquirer 430, AA_{w}(GDS, SEM) represents an alignment result between an inspection image and a reference image according to an alignment algorithm after applying alignment parameter set W to the inspection image or the reference image. In some embodiments, a cross-correlation maximization algorithm can be used as an alignment algorithm as an example. However, it should be noted that any alignment algorithm may be used in any embodiment of this disclosure, not limited to a cross-correlation maximization algorithm.

In some embodiments, a distance between an alignment result after applying alignment parameter set W and a target alignment is calculated. In some embodiments, a distance between the alignment result and the target alignment can be calculated as a distance between two vectors as expressed in equation 1. For example, when a position of a SEM pattern in a target alignment is expressed in vector V1 and a position of a corresponding SEM pattern in an alignment result is expressed in vector V2, a distance between two vectors V1 and V2 can be used as a distance between an alignment result and a target alignment. In some embodiments, a plurality of alignment parameter sets W can be considered, and a distance between an alignment result and a target alignment can be calculated for each alignment parameter set W. In some embodiments, alignment parameter set W can comprise a plurality of alignment parameters, and each set W can comprise a different parameter value combination of a plurality of alignment parameters. In some embodiments, among a plurality of alignment parameter sets, alignment parameter set W that provides the smallest distance can be selected as an estimated alignment parameter set W* as expressed by symbol Arg Min_{w} in Equation 1.

According to some embodiments of the present disclosure, estimated alignment parameter(s) can be provided to a user. In some embodiments, estimated alignment parameter(s) included in estimated alignment parameter set W* can be displayed on a display (not shown). FIG. 5C is an example alignment parameter table, consistent with embodiments of the present disclosure. As shown in FIG. 5C, a parameter P (e.g., parameters P1 to P3) can be provided along with its associated parameter value V (e.g., values V1 to V3).

In some embodiments, parameter P can include an image process option to be performed on an inspection image or a reference image, an image rendering option to be performed on a reference image, etc. In some embodiments, parameter value V can include a parameter value(s) for performing a corresponding image processing option, a corresponding image rendering option, etc. In some embodiments, parameter value V can include an estimation result whether a certain image process option is to be performed on an inspection image or a reference image, whether a certain rendering option is to be performed on a reference image, etc.

In an example shown in FIG. 5B, first alignment parameter P1 can be an image process option to be performed on an inspection image. For example, first alignment parameter P1 can be set as a gradient operation to be performed on inspection image 510. A gradient operation can be performed on inspection image 510 to detect edges of pattern 511 of inspection image 510 as edges of pattern 511 has a more distinctive gray level when compared with other areas. For example, as shown in FIG. 5B, edges of pattern 511 are brighter while a background of inspection image 510 and a portion inside of the edges are darker. In this example, first value V1 can be a parameter(s) for performing a gradient operation on inspection image 510 or an indication whether the gradient operation is to be performed or not.

In an example shown in FIG. 5B, second alignment parameter P2 can be a rendering option to be performed on a reference image. For example, second alignment parameter P2 can be set as an edge rendering option. Edge rendering can be performed to render only edges of reference image 520 into a gray level image rather than rendering the entire reference image 520 into a gray level image as the gray level may be constant inside and outside pattern 511 except edges. In this example, second value V2 can be a parameter(s) for performing edge rendering on reference image 520 or an indication whether the edge rendering is to be performed or not.

In an example shown in FIG. 5B, third alignment parameter P3 can be a convolution operation on reference image 520. As edges of pattern 521 of reference image 520 are sharper and thinner than those of pattern 511 of inspection image 510, a convolution operation can be performed on reference image 520 in order to render reference image 520 look similar to inspection image 510. In this example, third value V3 can be a parameter(s) for performing a convolution operation on reference image 520 or an indication whether the convolution operation is to be performed or not. For example, third value V3 can be a scale factor for a convolution operation. A scale factor for a convolution operation can be a filter kernel size. While a gradient operation, a rendering operation, a convolution operation, and a scale factor are illustrated as alignment parameters, it will be appreciated that the present disclosure can be appliable to any alignment parameters including any image processing operations.

Referring back to FIG. 4, according to some embodiments of the present disclosure, alignment parameter applier 450 can apply estimated alignment parameter(s) to an inspection image or a reference image. According to some embodiments, alignment parameter applier 450 can perform an estimated image processing option(s) according to an estimated value on an inspection image or a reference image. In an example referring to FIG. 5B, a gradient operation can be performed on inspection image 510, edge rendering can be performed on reference image 520, and a convolution operation with an estimated scale factor can be performed on reference image 520. In some embodiments, inspection image 510 and reference image 520 after applying estimated alignment parameter(s) can be aligned according to an alignment algorithm for post processing, e.g., for identifying defects, classifying defects, etc.

According to some embodiments of the present disclosure, estimated alignment parameter(s) obtained by alignment parameter estimator 440 can be applied to subsequent inspection image(s). In some embodiments, estimated alignment parameter(s) obtained for an inspection image can be applied to a batch of inspection images that have the same pattern as the inspection image or that are obtained under a same inspection condition as the inspection image. In some embodiments, an inspection condition includes, but is not limited to, a beam deflection degree, a system magnetic field, an operation voltage, a beam current, a target beam position on a wafer, etc.

As discussed, according to some embodiments of the present disclosure, a user-friendly parameter tuning method for aligning SEM images with design layout data can be provided. Embodiments of the present disclosure can provide a result-oriented auto parameter tuning technique for D2DB alignments that can considerably shorten alignment parameter tuning cycles compared to a conventional manual parameter tuning technique. The conventional manual approach involves iterative tuning cycles based on trial-and-error to find an optimal alignment parameter combination, which can be time-consuming and tedious. Under the current manual process, it could take up to 10 min to tune alignment parameters for image size 1024*1024 pixels to an acceptable level. According to some embodiments of the present disclosure, the time period for searching an optimal alignment parameter combination for image size 1024*1024 pixels can be reduced to less than a minute, e.g., 30 seconds.

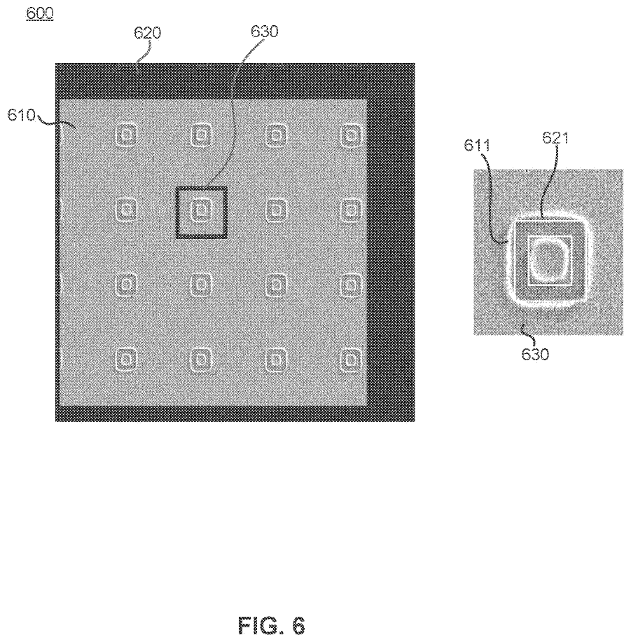

FIG. 6 illustrates an example alignment result according to estimated alignment parameters consistent with embodiments of the present disclosure. In FIG. 6, an inspection image 610 can be an image obtained by applying estimated alignment parameter(s) to inspection image 510 of FIG. 5A and a reference image 620 can be an image obtained by applying estimated alignment parameter(s) to reference image 520 of FIG. 5A. For example, inspection image 610 can be obtained by performing a gradient operation on inspection image 510 and reference image 620 can be obtained by performing edge rendering and a convolution operation with an estimated scale factor (e.g., scale adjust value from a default setting is 0.77) on reference image 520. According to some implementations, it takes about 54 seconds to search the alignment parameter combination for image size 2048*2048 pixels with a distance 0.31 pixel between a target alignment (e.g., shown in FIG. 5B) and an alignment result (e.g., shown in FIG. 6). An alignment result 600 shown in FIG. 6 is an alignment result between inspection image 610 and reference image 620 according to an alignment algorithm, e.g., SA alignment algorithm. Compared to alignment result 300 obtained without parameter tuning according to some embodiments of the present disclosure, it is noted that inspection image 610 is relatively well aligned with reference image 620 such that a center of a pattern 611 of inspection image 610 matches a center of a corresponding pattern 621 of reference image rather than snapping to one side despite the presence of the charging effect.

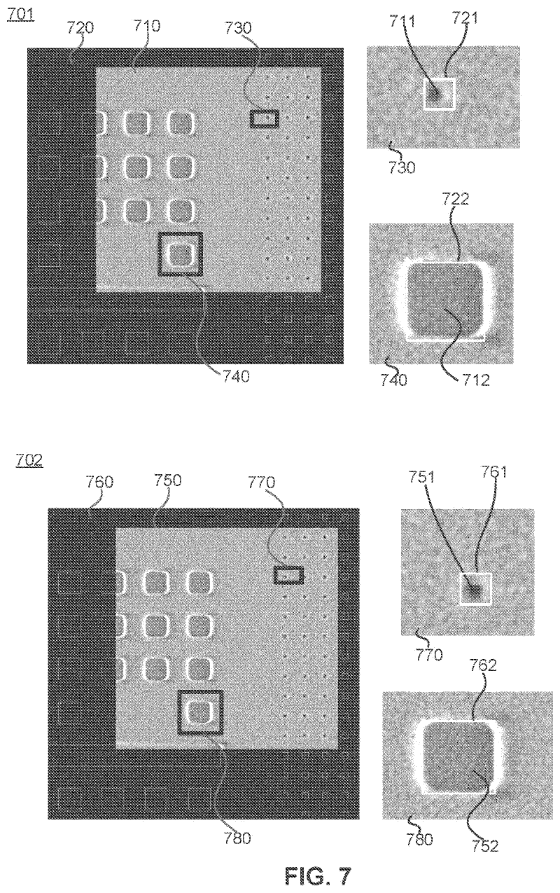

FIG. 7 illustrates a first example comparison between alignment results for a SEM image before and after applying estimated alignment parameter(s) according to some embodiment of the present disclosure. In FIG. 7, a first alignment result 701 is an alignment result between a SEM image 710 and a reference image 720 without parameter tuning according to some embodiments of the present disclosure. As shown in FIG. 7, first alignment result 701 includes two portions 730 and 740 of which enlarged images are illustrated on the right side. In the enlarged image of portion 730, a pattern 711 of SEM image 710 is snapped to a left side of a corresponding pattern 721 of reference image 720. Similarly, in the enlarged image of portion 740, a pattern 712 of SEM image 710 is snapped to a top side of a corresponding pattern 722 of reference image 720. Such snapping may be caused by asymmetric gray level around patterns 711 and 712 of SEM image 710.

A second alignment result 702 is an alignment result between an inspection image 750 and a corresponding reference image 760 where inspection image 750 is an image obtained by applying estimated alignment parameter(s) to SEM image 710 and reference image 760 is an image obtained by applying estimated alignment parameter(s) to reference image 720. For example, inspection image 750 can be obtained by performing a gradient operation on SEM image 710 and reference image 760 can be obtained by performing edge rendering and a convolution operation with an estimated scale factor (e.g., scale adjust value from a default setting is 0.01) on reference image 720. According to some implementations, it takes about 21 seconds to search the alignment parameter combination for image size 1024*1024 pixels. As shown in FIG. 7, second alignment result 702 also includes two portions 770 and 780 of which enlarged images are illustrated on the right side and that correspond to two portions 730 and 740. Compared to first alignment result 701, it is noted that patterns 751 and 752 of inspection image 750 are relatively well aligned with corresponding patterns 761 and 762 of reference image 760 at the center rather than snapping to one side as shown in the enlarged images of portions 770 and 780.

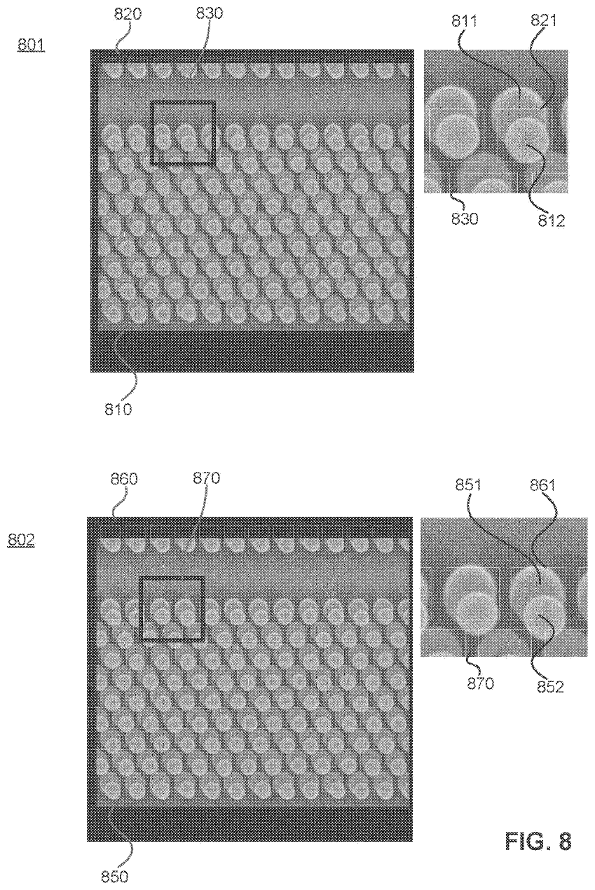

FIG. 8 illustrates a second example alignment result comparison for a SEM image before and after applying estimated alignment parameter(s) according to some embodiment of the present disclosure. In FIG. 8, a first alignment result 801 is an alignment result between a SEM image 810 and a reference image 820 without parameter tuning according to some embodiments of the present disclosure. As shown in FIG. 8, first alignment result 801 includes a portion 830 of which enlarged image is illustrated on the right side. In the enlarged image of portion 830, SEM image 810 include two patterns 811 and 812 of a circular shape and second pattern 812 of a smaller circle is aligned to a pattern 821 of reference image 820 while pattern 821 of reference image 820 corresponds to first pattern 811 of a larger circle. Such misalignments may be caused by intensity of second pattern 812 is stronger than that of first pattern and by tendency of an alignment algorithm along with a default parameter setting to align the intense pattern with a GDS pattern.

A second alignment result 802 is an alignment result between an inspection image 850 and a corresponding reference image 860 where inspection image 850 is an image obtained by applying estimated alignment parameter(s) to SEM image 810 and reference image 860 is an image obtained by applying estimated alignment parameter(s) to reference image 820. For example, inspection image 850 can be obtained by performing a gradient operation on SEM image 810 and reference image 860 can be obtained by performing edge rendering and a convolution operation with an estimated scale factor (e.g., scale adjust value from a default setting is 0.012) on reference image 820. According to some implementations, it takes about 56 seconds to search the alignment parameter combination for image size 4048*4048 pixels. As shown in FIG. 8, second alignment result 802 also includes a portion 870 of which enlarged image is illustrated on the right side, and portion 870 corresponds to portion 830 of first alignment result 801. Compared to first alignment result 801, it is noted that first pattern 851 of a larger circle is aligned to corresponding pattern 861 of reference image 860 rather than aligning second pattern 852 with pattern 861 as shown in the enlarged image of portion 870.

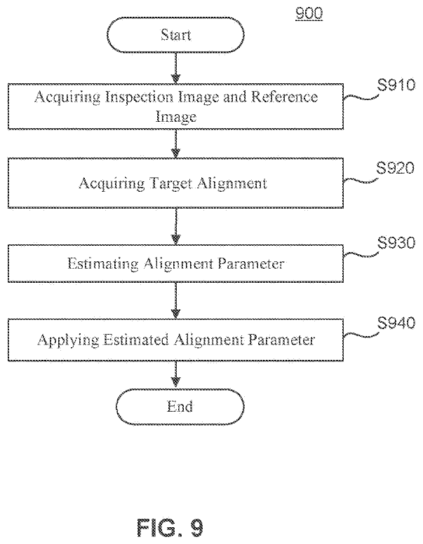

FIG. 9 is a process flowchart representing an exemplary alignment parameter tuning method, consistent with embodiments of the present disclosure. The steps of method 900 can be performed by a system (e.g., system 400 of FIG. 4) executing on or otherwise using the features of a computing device, e.g., controller 109 of FIG. 1. It is appreciated that the illustrated method 900 can be altered to modify the order of steps and to include additional steps.

In step S910, an inspection image is acquired reference image are acquired. Step S910 can be performed by, for example, inspection image acquirer 410 or reference image acquirer 420, among others. In some embodiments, an inspection image is a SEM image of a sample or a wafer. In some embodiments, a reference image can be a layout file for a wafer design corresponding to the inspection image. In some embodiments, a reference image can be an image rendered from the layout file.

In step S920, a target alignment between an inspection image and a reference image is acquired. Step S920 can be performed by, for example, target alignment acquirer 430, among others. In some embodiments, a target alignment can be pattern matching information between an inspection image and a reference image. In some embodiments, a target alignment can be acquired from user input aligning an inspection image with a corresponding reference image.

FIG. 5B illustrates inspection image 510 aligned with reference image 520, consistent with embodiments of the present disclosure. According to some embodiments, inspection image 510 and reference image 520 can be positioned such that pattern 511 of inspection image 510 and corresponding pattern 521 of reference image 520 match each other. In some embodiments, a user may move inspection image 510 to a position such that pattern 511 of inspection image 510 overlaps with corresponding pattern 521 of reference image 520. As shown in enlarged image of portion 530 in FIG. 5B, inspection image 510 and reference image 520 can be positioned such that a center of pattern 511 of inspection image 510 and a center of pattern 521 of reference image 520 matches. According to some embodiments of the present disclosure, alignment information between inspection image 510 and reference image 520 illustrated in FIG. 5B can be a target alignment between inspection image 510 and reference image 520. In some embodiments, FIG. 5A and FIG. 5B may illustrate images 501 and 502 displayed on a displayer (not shown), and a user may move inspection image 510 from a position in FIG. 5A to a position in FIG. 5B, e.g., by dragging inspection image 510 to a target position to provide a target alignment.

In step S930, an alignment parameter(s) is estimated based on a target alignment acquired in step S920. Step S930 can be performed by, for example, alignment parameter estimator 440, among others. In some embodiments, a target alignment acquired in step S920 can provide guidance how to tune alignment parameter(s) to achieve the target alignment. According to some embodiments of the present disclosure, alignment parameter(s) can be determined such that an alignment between an inspection image and a reference image after applying the estimated alignment parameter(s) can be as close as possible to the target alignment. The process of estimating alignment parameter(s) has been described with respect to Equation 1 and FIG. 5C, and thus the detailed explanation will be omitted here for simplicity purposes.

In step S940, an estimated alignment parameter(s) acquired in step S930 is applied to an inspection image or a reference image. Step S940 can be performed by, for example, estimated alignment parameter applier 450, among others. According to some embodiments, an estimated image processing option(s) according to an estimated value can be performed on an inspection image or a reference image. According to some embodiments of the present disclosure, estimated alignment parameter(s) can be applied to subsequent inspection image(s). In some embodiments, estimated alignment parameter(s) obtained for an inspection image can be applied to a batch of inspection images that have the same pattern as the inspection image or that are obtained under a same inspection condition as the inspection image. In some embodiments, an inspection condition includes, but is not limited to, a beam deflection degree, a system magnetic field, an operation voltage, a beam current, a target beam position on a wafer, etc.

A non-transitory computer readable medium may be provided that stores instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, and method 900. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method for image alignment of an inspection image, comprising:
   acquiring an inspection image;
   acquiring a reference image corresponding to the inspection image;
   acquiring a target alignment between the inspection image and the reference image based on characteristics of the inspection image and the reference image;
   estimating an alignment parameter based on the target alignment; and
   applying the alignment parameter to a subsequent inspection image.
2. The method of clause 1, wherein acquiring the target alignment comprises:
   acquiring the target alignment between the inspection image and the reference image, the target alignment being a placement of the inspection image or the reference image in a position such that a pattern of the inspection image matches a corresponding pattern of the reference image.
3. The method of clause 1, wherein acquiring the target alignment comprises:
   acquiring the target alignment between the inspection image and the reference image from a user input of dragging the inspection image or the reference image in a position such that a center of a pattern of the inspection image matches a center of a corresponding pattern of the reference image.
4. The method of any one of clauses 1-3, wherein estimating the alignment parameter comprises:
   applying a plurality of candidate alignment parameters to the inspection image;
   acquiring a plurality of alignment results between the inspection image and the reference image after applying the plurality of candidate alignment parameters;
determining a plurality of distances between the plurality of alignment results and the target alignment; and
   selecting, among the plurality of candidate alignment parameters, a candidate alignment parameter associated with a smallest distance among the plurality of distances as the alignment parameter.
5. The method of any one of clauses 1-3, wherein the alignment parameter comprises an alignment parameter combination including multiple alignment parameters and estimating the alignment parameter further comprises:
   applying a plurality of candidate alignment parameter combinations to the inspection image or the reference image;
   acquiring a plurality of alignment results between the inspection image and the reference image after applying the plurality of candidate alignment parameter combinations;
   determining a plurality of distances between the plurality of alignment results and the target alignment; and
   selecting, among the plurality of candidate alignment parameter combinations, a candidate alignment parameter combination associated with a smallest distance among the plurality of distances as the alignment parameter.
6. The method of any one of clauses 1-5, wherein the alignment parameter comprises an alignment parameter combination including multiple alignment parameters and the method further comprises:
   applying at least one alignment parameters among the multiple alignment parameters to the reference image.
7. The method of any one of clauses 1-6, wherein the reference image is layout data in Graphic Database System (GDS) format, Graphic Database System II (GDS II) format, Open Artwork System Interchange Standard (OASIS) format, or Caltech Intermediate Format (CIF).
8. The method of any one of clauses 1-7, wherein the subsequent inspection image has a same pattern as the inspection image.
9. A method for image alignment of an inspection image, comprising:
   acquiring an inspection image;
   acquiring a reference image corresponding to the inspection image;
   acquiring a target alignment between the inspection image and the reference image based on a pattern of the inspection image and a corresponding pattern of the reference image;
   evaluating a first alignment parameter combination and a second alignment parameter combination based on the target alignment;
   selecting, between the first and second alignment parameter combinations, one alignment parameter combination based on the evaluation; and
   applying the selected alignment parameter combination to the reference image.
10. The method of clause 9, wherein acquiring the target alignment comprises:
   acquiring the target alignment between the inspection image and the reference image, the target alignment being a placement of the inspection image or the reference image in a position such that a pattern of the inspection image matches a corresponding pattern of the reference image.
11. The method of clause 9, wherein acquiring the target alignment comprises:
   acquiring the target alignment between the inspection image and the reference image from a user input of dragging the inspection image or the reference image in a position such that a center of a pattern of the inspection image matches a center of a corresponding pattern of the reference image.
12. The method of any one of clauses 9-11, wherein selecting, between the first and second alignment parameter combinations, one alignment parameter combination based on evaluation comprises:
   applying the first alignment parameter combination and the second alignment parameter combination to the inspection image or the reference image;
   acquiring a first alignment result between the inspection image and the reference image after applying the first alignment parameter combination and a second alignment result between the inspection image and the reference image after applying the second alignment parameter combination;
   determining a first distance between the first alignment result and the target alignment and a second distance between the second alignment result and the target alignment; and
   selecting, between the first and second alignment parameter combinations, one alignment parameter combination associated with a smaller distance between the first and second distances.
13. The method of any one of clauses 9-12, wherein the first and second alignment parameter combinations include multiple alignment parameters.
14. The method of clause 13, further comprising:
   applying at least one alignment parameter among the multiple alignment parameters in the selected alignment parameter combination to a subsequent inspection image.
15. The method of clause 14, wherein the subsequent inspection image has a same pattern as the inspection image.
16. The method of any one of clauses 9-15, wherein the reference image is layout data in Graphic Database System (GDS) format, Graphic Database System II (GDS II) format, Open Artwork System Interchange Standard (OASIS) format, or Caltech Intermediate Format (CIF).
17. An apparatus for image alignment of an inspection image, comprising:
   a memory storing a set of instructions; and
   at least one processor configured to execute the set of instructions to cause the apparatus to perform:
   acquiring an inspection image;
   acquiring a reference image corresponding to the inspection image;
   acquiring a target alignment between the inspection image and the reference image based on characteristics of the inspection image and the reference image;
   estimating an alignment parameter based on the target alignment; and
   applying the alignment parameter to a subsequent inspection image.
18. The apparatus of clause 17, wherein, in acquiring the target alignment, the at least one processor is configured to execute the set of instructions to cause the apparatus to perform:
   acquiring the target alignment between the inspection image and the reference image, the target alignment being a placement of the inspection image or the reference image in a position such that a pattern of the inspection image matches a corresponding pattern of the reference image.
19. The apparatus of clause 17, wherein, in acquiring the target alignment, the at least one processor is configured to execute the set of instructions to cause the apparatus to perform:
   acquiring the target alignment between the inspection image and the reference image from a user input of dragging the inspection image or the reference image in a position such that a center of a pattern of the inspection image matches a center of a corresponding pattern of the reference image.
20. The apparatus of any one of clauses 17-19, wherein, in estimating the alignment parameter, the at least one processor is configured to execute the set of instructions to cause the apparatus to perform:
   applying a plurality of candidate alignment parameters to the inspection image;
   acquiring a plurality of alignment results between the inspection image and the reference image after applying the plurality of candidate alignment parameters;
   determining a plurality of distances between the plurality of alignment results and the target alignment; and
   selecting, among the plurality of candidate alignment parameters, a candidate alignment parameter associated with a smallest distance among the plurality of distances as the alignment parameter.
21. The apparatus of any one of clauses 17-19, wherein the alignment parameter comprises an alignment parameter combination including multiple alignment parameters and, in estimating the alignment parameter, the at least one processor is configured to execute the set of instructions to cause the apparatus to perform:
   applying a plurality of candidate alignment parameter combinations to the inspection image or the reference image;
   acquiring a plurality of alignment results between the inspection image and the reference image after applying the plurality of candidate alignment parameter combinations;
   determining a plurality of distances between the plurality of alignment results and the target alignment; and
   selecting, among the plurality of candidate alignment parameter combinations, a candidate alignment parameter combination associated with a smallest distance among the plurality of distances as the alignment parameter.
22. The apparatus of any one of clauses 17-21, wherein the alignment parameter comprises an alignment parameter combination including multiple alignment parameters and the at least one processor is configured to execute the set of instructions to cause the apparatus to further perform:
   applying at least one alignment parameters among the multiple alignment parameters to the reference image.
23. The apparatus of any one of clauses 17-22, wherein the reference image is layout data in Graphic Database System (GDS) format, Graphic Database System II (GDS II) format, Open Artwork System Interchange Standard (OASIS) format, or Caltech Intermediate Format (CIF).
24. The apparatus of any one of clauses 17-23, wherein the subsequent inspection image has a same pattern as the inspection image.
25. An apparatus for image alignment of an inspection image, comprising:
   a memory storing a set of instructions; and
   at least one processor configured to execute the set of instructions to cause the apparatus to perform:
   acquiring an inspection image;
   acquiring a reference image corresponding to the inspection image;
   acquiring a target alignment between the inspection image and the reference image based on a pattern of the inspection image and a corresponding pattern of the reference image;
   evaluating a first alignment parameter combination and a second alignment parameter combination based on the target alignment;
   selecting, between the first and second alignment parameter combinations, one alignment parameter combination based on the evaluation; and
   applying the selected alignment parameter combination to the reference image.
26. The apparatus of clause 25, wherein, in acquiring the target alignment, the at least one processor is configured to execute the set of instructions to cause the apparatus to perform:
   acquiring the target alignment between the inspection image and the reference image, the target alignment being a placement of the inspection image or the reference image in a position such that a pattern of the inspection image matches a corresponding pattern of the reference image.
27. The apparatus of clause 25, wherein, in acquiring the target alignment, the at least one processor is configured to execute the set of instructions to cause the apparatus to perform:
   acquiring the target alignment between the inspection image and the reference image from a user input of dragging the inspection image or the reference image in a position such that a center of a pattern of the inspection image matches a center of a corresponding pattern of the reference image.
28. The apparatus of any one of clauses 25-27, wherein, in selecting one alignment parameter combination based on evaluation, the at least one processor is configured to execute the set of instructions to cause the apparatus to perform:
   applying the first alignment parameter combination and the second alignment parameter combination to the inspection image or the reference image;
   acquiring a first alignment result between the inspection image and the reference image after applying the first alignment parameter combination and a second alignment result between the inspection image and the reference image after applying the second alignment parameter combination;
   determining a first distance between the first alignment result and the target alignment and a second distance between the second alignment result and the target alignment; and
   selecting, between the first and second alignment parameter combinations, one alignment parameter combination associated with a smaller distance between the first and second distances.
29. The apparatus of any one of clauses 25-27, wherein the first and second alignment parameter combinations include multiple alignment parameters.
30. The apparatus of clause 29, wherein the at least one processor is configured to execute the set of instructions to cause the apparatus to further perform:
   applying at least one alignment parameter among the multiple alignment parameters in the selected alignment parameter combination to a subsequent inspection image.
31. The apparatus of clause 30, wherein the subsequent inspection image has a same pattern as the inspection image.
32. The apparatus of any one of clauses 27-31, wherein the reference image is layout data in Graphic Database System (GDS) format, Graphic Database System II (GDS II) format, Open Artwork System Interchange Standard (OASIS) format, or Caltech Intermediate Format (CIF).
33. A non-transitory computer readable medium that stores a set of instructions that is executable by at least on processor of a computing device to cause the computing device to perform a method for image alignment of an inspection image, the method comprising:
   acquiring an inspection image;
   acquiring a reference image corresponding to the inspection image;
   acquiring a target alignment between the inspection image and the reference image based on characteristics of the inspection image and the reference image;
   estimating an alignment parameter based on the target alignment; and
   applying the alignment parameter to a subsequent inspection image.
34. The computer readable medium of clause 33, wherein, in acquiring the target alignment, the set of instructions that is executable by at least one processor of the computing device cause the computing device to perform:
   acquiring the target alignment between the inspection image and the reference image, the target alignment being a placement of the inspection image or the reference image in a position such that a pattern of the inspection image matches a corresponding pattern of the reference image.
35. The computer readable medium of clause 33, wherein, in acquiring the target alignment, the set of instructions that is executable by at least one processor of the computing device cause the computing device to perform:
   acquiring the target alignment between the inspection image and the reference image from a user input of dragging the inspection image or the reference image in a position such that a center of a pattern of the inspection image matches a center of a corresponding pattern of the reference image.
36. The computer readable medium of any one of clauses 33-35, wherein, in estimating the alignment parameter, the set of instructions that is executable by at least one processor of the computing device cause the computing device to perform:
   applying a plurality of candidate alignment parameters to the inspection image;
   acquiring a plurality of alignment results between the inspection image and the reference image after applying the plurality of candidate alignment parameters;
   determining a plurality of distances between the plurality of alignment results and the target alignment; and
   selecting, among the plurality of candidate alignment parameters, a candidate alignment parameter associated with a smallest distance among the plurality of distances as the alignment parameter.
37. The computer readable medium of any one of clauses 33-35, wherein the alignment parameter comprises an alignment parameter combination including multiple alignment parameters and, in estimating the alignment parameter, the set of instructions that is executable by at least one processor of the computing device cause the computing device to perform:
   applying a plurality of candidate alignment parameter combinations to the inspection image or the reference image;
   acquiring a plurality of alignment results between the inspection image and the reference image after applying the plurality of candidate alignment parameter combinations;
   determining a plurality of distances between the plurality of alignment results and the target alignment; and
   selecting, among the plurality of candidate alignment parameter combinations, a candidate alignment parameter combination associated with a smallest distance among the plurality of distances as the alignment parameter.
38. The computer readable medium of any one of clauses 33-37, wherein the alignment parameter comprises an alignment parameter combination including multiple alignment parameters and the set of instructions that is executable by at least one processor of the computing device cause the computing device to further perform:
   applying at least one alignment parameters among the multiple alignment parameters to the reference image.
39. The computer readable medium of any one of clauses 33-38, wherein the reference image is layout data in Graphic Database System (GDS) format, Graphic Database System II (GDS II) format, Open Artwork System Interchange Standard (OASIS) format, or Caltech Intermediate Format (CIF).
40. The computer readable medium of any one of clauses 33-39, wherein the subsequent inspection image has a same pattern as the inspection image.
41. A non-transitory computer readable medium that stores a set of instructions that is executable by at least on processor of a computing device to cause the computing device to perform a method for method for image alignment of an inspection image, the method comprising
   acquiring an inspection image;
   acquiring a reference image corresponding to the inspection image;
   acquiring a target alignment between the inspection image and the reference image based on a pattern of the inspection image and a corresponding pattern of the reference image;
   evaluating a first alignment parameter combination and a second alignment parameter combination based on the target alignment;
   selecting, between the first and second alignment parameter combinations, one alignment parameter combination based on the evaluation; and
   applying the selected alignment parameter combination to the reference image.
42. The computer readable medium of clause 41, wherein, in acquiring the target alignment, the set of instructions that is executable by at least one processor of the computing device cause the computing device to perform:
   acquiring the target alignment between the inspection image and the reference image, the target alignment being a placement of the inspection image or the reference image in a position such that a pattern of the inspection image matches a corresponding pattern of the reference image.
43. The computer readable medium of clause 41, wherein, in acquiring the target alignment, the set of instructions that is executable by at least one processor of the computing device cause the computing device to perform:
   acquiring the target alignment between the inspection image and the reference image from a user input of dragging the inspection image or the reference image in a position such that a center of a pattern of the inspection image matches a center of a corresponding pattern of the reference image.
44. The computer readable medium of any one of clauses 41-43, wherein, in selecting one alignment parameter combination based on evaluation, the set of instructions that is executable by at least one processor of the computing device cause the computing device to perform:
   applying the first alignment parameter combination and the second alignment parameter combination to the inspection image or the reference image;
   acquiring a first alignment result between the inspection image and the reference image after applying the first alignment parameter combination and a second alignment result between the inspection image and the reference image after applying the second alignment parameter combination;
   determining a first distance between the first alignment result and the target alignment and a second distance between the second alignment result and the target alignment; and
   selecting, between the first and second alignment parameter combinations, one alignment parameter combination associated with a smaller distance between the first and second distances.
45. The computer readable medium of any one of clauses 41-44, wherein the first and second alignment parameter combinations include multiple alignment parameters.
46. The computer readable medium of clause 45, wherein the set of instructions that is executable by at least one processor of the computing device cause the computing device to further perform:
   applying at least one alignment parameter among the multiple alignment parameters in the selected alignment parameter combination to a subsequent inspection image.
47. The computer readable medium of clause 46, wherein the subsequent inspection image has a same pattern as the inspection image.
48. The computer readable medium of any one of clauses 41-47, wherein the reference image is layout data in Graphic Database System (GDS) format, Graphic Database System II (GDS II) format, Open Artwork System Interchange Standard (OASIS) format, or Caltech Intermediate Format (CIF).

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for image alignment of an inspection image, comprising:
acquiring an inspection image;
acquiring a reference image corresponding to the inspection image;
acquiring a target alignment between the inspection image and the reference image based on a pattern of the inspection image and a corresponding pattern of the reference image;
evaluating a first alignment parameter combination and a second alignment parameter combination based on the target alignment;
selecting, between the first and second alignment parameter combinations, one alignment parameter combination based on the evaluation; and
applying the selected alignment parameter combination to the reference image.

2. The method of claim 1, wherein acquiring the target alignment comprises:
acquiring the target alignment between the inspection image and the reference image, the target alignment being a placement of the inspection image or the reference image in a position such that a pattern of the inspection image matches a corresponding pattern of the reference image.

3. The method of claim 1, wherein acquiring the target alignment comprises:
acquiring the target alignment between the inspection image and the reference image from a user input of dragging the inspection image or the reference image in a position such that a center of a pattern of the inspection image matches a center of a corresponding pattern of the reference image.

4. The method of claim 1, wherein selecting, between the first and second alignment parameter combinations, one alignment parameter combination based on evaluation comprises:
applying the first alignment parameter combination and the second alignment parameter combination to the inspection image or the reference image;
acquiring a first alignment result between the inspection image and the reference image after applying the first alignment parameter combination and a second alignment result between the inspection image and the reference image after applying the second alignment parameter combination;
determining a first distance between the first alignment result and the target alignment and a second distance between the second alignment result and the target alignment; and
selecting, between the first and second alignment parameter combinations, one alignment parameter combination associated with a smaller distance between the first and second distances.

5. The method of claim 1, wherein the first and second alignment parameter combinations include multiple alignment parameters.

6. The method of claim 5, further comprising:
applying at least one alignment parameter among the multiple alignment parameters in the selected alignment parameter combination to a subsequent inspection image.

7. The method of claim 6, wherein the subsequent inspection image has a same pattern as the inspection image.

8. An apparatus for image alignment of an inspection image, comprising:
a memory storing a set of instructions; and
at least one processor configured to execute the set of instructions to cause the apparatus to perform:
acquiring an inspection image;
acquiring a reference image corresponding to the inspection image;
acquiring a target alignment between the inspection image and the reference image based on characteristics of the inspection image and the reference image;
estimating an alignment parameter based on the target alignment; and
applying the alignment parameter to a subsequent inspection image.

9. The apparatus of claim 8, wherein, in acquiring the target alignment, the at least one processor is configured to execute the set of instructions to cause the apparatus to perform:
acquiring the target alignment between the inspection image and the reference image, the target alignment being a placement of the inspection image or the reference image in a position such that a pattern of the inspection image matches a corresponding pattern of the reference image.

10. The apparatus of claim 8, wherein, in acquiring the target alignment, the at least one processor is configured to execute the set of instructions to cause the apparatus to perform:
acquiring the target alignment between the inspection image and the reference image from a user input of dragging the inspection image or the reference image in a position such that a center of a pattern of the inspection image matches a center of a corresponding pattern of the reference image.

11. The apparatus of claim 8, wherein, in estimating the alignment parameter, the at least one processor is configured to execute the set of instructions to cause the apparatus to perform:
applying a plurality of candidate alignment parameters to the inspection image;
acquiring a plurality of alignment results between the inspection image and the reference image after applying the plurality of candidate alignment parameters;
determining a plurality of distances between the plurality of alignment results and the target alignment; and
selecting, among the plurality of candidate alignment parameters, a candidate alignment parameter associated with a smallest distance among the plurality of distances as the alignment parameter.

12. The apparatus of claim 8, wherein the alignment parameter comprises an alignment parameter combination including multiple alignment parameters and, in estimating the alignment parameter, the at least one processor is configured to execute the set of instructions to cause the apparatus to perform:
applying a plurality of candidate alignment parameter combinations to the inspection image or the reference image;
acquiring a plurality of alignment results between the inspection image and the reference image after applying the plurality of candidate alignment parameter combinations;
determining a plurality of distances between the plurality of alignment results and the target alignment; and
selecting, among the plurality of candidate alignment parameter combinations, a candidate alignment parameter combination associated with a smallest distance among the plurality of distances as the alignment parameter.

13. The apparatus of claim 8, wherein the alignment parameter comprises an alignment parameter combination including multiple alignment parameters and the at least one processor is configured to execute the set of instructions to cause the apparatus to further perform:
applying at least one alignment parameters among the multiple alignment parameters to the reference image.

14. The apparatus of claim 8, wherein the reference image is layout data in Graphic Database System (GDS) format, Graphic Database System II (GDS II) format, Open Artwork System Interchange Standard (OASIS) format, or Caltech Intermediate Format (CIF).

15. The apparatus of claim 8, wherein the subsequent inspection image has a same pattern as the inspection image.

16. A non-transitory computer readable medium that stores a set of instructions that is executable by at least one processor of a computing device to cause the computing device to perform operations for image alignment of an inspection image, the operations comprising:
acquiring an inspection image;
acquiring a reference image corresponding to the inspection image;
acquiring a target alignment between the inspection image and the reference image based on characteristics of the inspection image and the reference image;
estimating an alignment parameter based on the target alignment; and
applying the alignment parameter to a subsequent inspection image.

17. The computer readable medium of claim 16, wherein, in acquiring the target alignment, the operations further comprise:
acquiring the target alignment between the inspection image and the reference image, the target alignment being a placement of the inspection image or the reference image in a position such that a pattern of the inspection image matches a corresponding pattern of the reference image.

18. The computer readable medium of claim 16, wherein, in acquiring the target alignment, the operations further comprise:
acquiring the target alignment between the inspection image and the reference image from a user input of dragging the inspection image or the reference image in a position such that a center of a pattern of the inspection image matches a center of a corresponding pattern of the reference image.

19. The computer readable medium of claim 16, wherein, in estimating the alignment parameter, the operations further comprise:
applying a plurality of candidate alignment parameters to the inspection image;
acquiring a plurality of alignment results between the inspection image and the reference image after applying the plurality of candidate alignment parameters;
determining a plurality of distances between the plurality of alignment results and the target alignment; and
selecting, among the plurality of candidate alignment parameters, a candidate alignment parameter associated with a smallest distance among the plurality of distances as the alignment parameter.

20. The computer readable medium of claim 16, wherein the alignment parameter comprises an alignment parameter combination including multiple alignment parameters and, in estimating the alignment parameter, the operations further comprise:
applying a plurality of candidate alignment parameter combinations to the inspection image or the reference image;
acquiring a plurality of alignment results between the inspection image and the reference image after applying the plurality of candidate alignment parameter combinations;
determining a plurality of distances between the plurality of alignment results and the target alignment; and
selecting, among the plurality of candidate alignment parameter combinations, a candidate alignment parameter combination associated with a smallest distance among the plurality of distances as the alignment parameter.
